(19) United States
(12) Patent Application Publication
(10) Pub. No.: US 2013/0017495 A1
(43) Pub. Date: Jan. 17, 2013

(54) INTERFERENCE EXPOSURE APPARATUS, INTERFERENCE EXPOSURE METHOD, AND MANUFACTURING METHOD OF SEMICONDUCTOR DEVICE

(71) Applicants: Katsuyoshi Kodera, Kanagawa (JP); Satoshi Tanaka, Kanagawa (JP)

(72) Inventors: Katsuyoshi Kodera, Kanagawa (JP); Satoshi Tanaka, Kanagawa (JP)

(21) Appl. No.: 13/417,968

(22) Filed: Mar. 12, 2012

(30) Foreign Application Priority Data
Jul. 15, 2011 (JP) 2011-156965

(51) Int. Cl. G03F 7/20; G03B 27/54

(52) U.S. Cl. 430/319; 355/67

(57) ABSTRACT

According to one embodiment, an interference exposure apparatus of the embodiment includes a light path changing section in which a changing element adapted to change a light path direction and a light path length of a plurality of light beams with respect to the plurality of light beams having coherency with respect to each other is arranged substantially axisymmetrically; and an adjusting section for adjusting one part of the light beam entering a substrate by intensity changing or phase changing one part of the light beam corresponding to a pattern shape to form on the substrate. A light beam exit from the light path changing section and the adjusting section is interfered on the substrate to carry out an interference exposure on the substrate.

### CROSS-REFERENCE TO RELATED APPLICATIONS

This application is based upon and claims the benefit of priority from Japanese Patent Application No. 2011-156965, filed on Jul. 15, 2011; the entire contents of which are incorporated herein by reference.

### FIELD

Embodiments described herein relate generally to an interference exposure apparatus, an interference exposure method, and a manufacturing method of a semiconductor device.

### BACKGROUND

An EUV (Extreme Ultra-Violet) exposure apparatus is known as one lithography device used to manufacture a semiconductor circuit of a next generation, but such EUV exposure apparatus is very expensive. Thus, a low cost lithography device that uses a method called an interference exposure technique is recently given attention.

The interference exposure technique does not require a complicated projection optical system, and can realize lower manufacturing cost since it does not require a mask or is mask-less. However, in the conventional interference exposure, a simple periodic pattern such as an LS (Line & Space) pattern or a grating pattern can be formed, but a complicated layout pattern such as an IC circuit is difficult to form. The conventional lithography method using a projection optical system and a mask is hereinafter referred to as an optical lithography to distinguish from the interference exposure technique.

A few methods have been proposed to solve the above problem.

(1) A method (method by Mix & Match with optical lithography: Imaging interference lithography) of creating a complicated IC circuit pattern at low cost by carrying out patterning by combining the conventional optical lithography technique of low NA and the interference exposure technique has been proposed. In this technique, a projection lens system, although low NA, is necessary, and a mask is also necessary, and hence the manufacturing cost increases.

(2) A method (multiple interference exposure) of forming a complicated pattern by multiple exposing the interference exposure two or more times has been proposed. In this technique, the pattern that can be formed is limited only to a simple two-dimensional pattern such as a grating pattern, and many optical systems need to be reset to generate a plurality of complicated IC circuit patterns. Thus, the flow becomes more complicated and the processing TAT becomes large.

(3) An interference exposure method using a multiple light beam of three or more that has coherency with each other has been proposed. In this technique, a depth of field (DoF) becomes small if the incident angle of the multiple light beam to the wafer is not appropriately set. Thus, it is not appropriate for the patterning of the semiconductor circuit in which the patterning is carried out on a two-dimensional plane. The resetting of many optical systems is required to form a plurality of complicated IC circuit patterns, and hence the flow becomes complicated and the processing TAT becomes large.

Therefore, it is desired to form various patterns easily and at low cost.

### BRIEF DESCRIPTION OF THE DRAWINGS

FIG. 1 is a diagram showing a schematic configuration of an interference exposure apparatus according to a first embodiment;

FIG. 2 is a diagram showing a configuration example of the interference exposure apparatus according to the first embodiment;

FIGS. 3A to 3C are diagrams respectively showing one example of a pinhole aperture, a ring-shaped aperture, and an incident region limiting section;

FIGS. 4A and 4B are diagrams describing a beam coordinate system;

FIGS. 5A to 5C are diagrams describing a relationship of a distance from an optical axis of each beam and the DoF;

FIG. 6 is a diagram showing a configuration of an interference exposure apparatus according to a second embodiment;

FIG. 7 is a diagram showing a configuration of a diffraction grating;

FIGS. 8A to 8D are diagrams showing a relationship of a light shielding section and an imaging pattern;

FIG. 9 is a diagram showing a configuration of a micro-mirror ring;

FIG. 10 is a top view showing a configuration example of a shutter section;

FIGS. 11A and 11B are diagrams showing another configuration example of a pattern adjusting section;

FIGS. 12A to 12C are top views showing a configuration of a plurality of light path changing sections;

FIG. 13 is a diagram showing a configuration of a light path changing section according to a fourth embodiment;

FIG. 14 is a diagram showing a configuration of a polarization section according to a fifth embodiment;

FIGS. 15A and 15B are diagrams showing a configuration of a phase adjustor according to a sixth embodiment; and

FIGS. 16A and 16B are diagrams showing a configuration of an incident angle filtering section according to a seventh embodiment.

### DETAILED DESCRIPTION

In general, according to embodiments, an interference exposure apparatus is provided. The interference exposure apparatus includes a light path changing section in which a changing element adapted to change the light path direction and the light path length of a plurality of light beams with respect to the plurality of light beams having coherency with respect to each other is arranged substantially axisymmetrically; and an adjusting section for adjusting one part of the light beam entering a substrate by intensity changing or phase changing one part of the light beam corresponding to a pattern shape to form on the substrate. The light beam exit from the light path changing section and the adjusting section is interfered on the substrate to carry out the interference exposure on the substrate.

Exemplary embodiments of an interference exposure apparatus, an interference exposure method, and a manufacturing method of a semiconductor device will be explained below in detail with reference to the accompanying drawings. The present invention is not limited to the following embodiments.

### First Embodiment

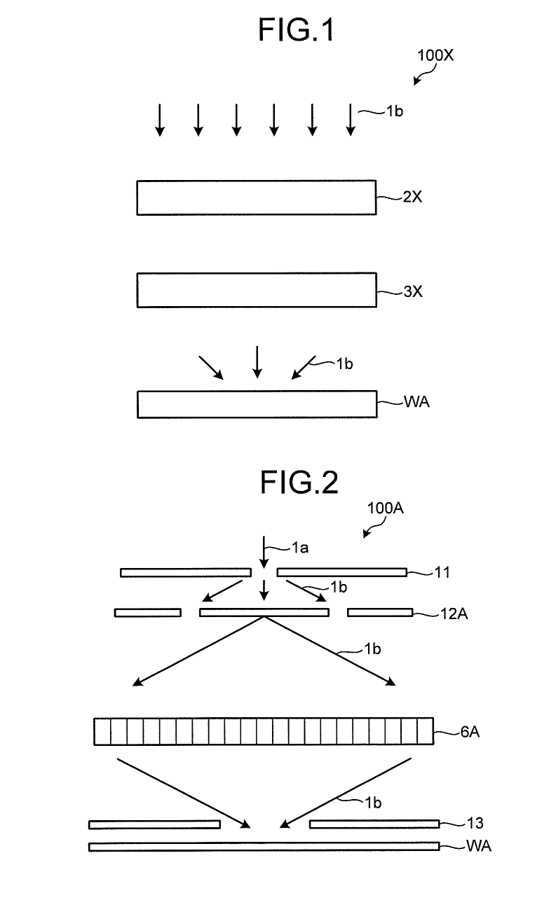

FIG. 1 is a diagram showing a schematic configuration of an interference exposure apparatus according to a first embodiment. A schematic view of a cross-sectional configuration of an interference exposure apparatus 100X is shown here. The interference exposure apparatus 100X of the present embodiment has an optical device (light path changing section 2X) for changing an advancing direction of a multi-light beam (coherent light beam) 1b of single wavelength having coherency in a ring shape. A patterning on a resist is carried out using an interference pattern formed by entering the multi-light beam 1b exit from the light path changing section 2X arranged in the ring shape to a wafer (substrate to be processed) WA. According to such configuration, the interference exposure apparatus 100X forms a pattern variation of high degree of freedom at sufficient focal depth.

The interference exposure apparatus 100X is configured to include the light path changing section 2X and a pattern adjusting section 3X. The light path changing section 2X is a device for changing the light path direction and the light path length of the multi-light beam 1b, and has a substantially axisymmetric configuration with respect to an optical axis of the multi-light beam 1b. The light path changing section 2X is configured to include a diffraction grating, a mirror (micro-mirror), and a prism. The diffraction grating and the mirror are arranged to be substantially axisymmetric at substantially equal distance from the optical axis, for example. The configuring element (micro-mirror ring etc.) of the light path changing section 2X is arranged at equal distance from the optical axis of the multi-light beam 1b, so that each configuring element is arranged in a ring shape.

The pattern adjusting section 3X is a device for changing the intensity or the phase of the light beam of the multi-light beam 1b, and has a function of changing the intensity or the phase of one part of the light beam. The pattern adjusting section 3X is configured using a plurality of shutters (light shielding body) that can be freely opened and closed, two polarization plates or a light path length changing device (phase adjustor) etc.

The shutters and a pair of polarization plates adjust the intensity of the light beam, and the light path length changing device changes the phase of the light beam by changing the light path length. Each shutter is configured to adjust whether or not to advance the multi-light beam 1b in which the light path is changed by the light path changing section 2X to the wafer WA of the wafer stage (not shown) by being opened or closed. The pattern variation to form on the wafer WA can be determined by adjusting the pattern adjusting section 3X (e.g., opening/closing of shutter).

A circular column shaped prism may be arranged between the wafer WA and the pattern adjusting section 3X. The distance between the wafer WA and the pattern adjusting section 3X thus can be formed long, and the substances generated from the wafer WA can be prevented from influencing the pattern adjusting section 3X. In the interference exposure apparatus 100X, either one of the light path changing section 2X and the pattern adjusting section 3X may be arranged on an upstream side (light source side) of the light path.

The electromagnetic wave (coherent light beam) of single wavelength exit from the light source (not shown) is converted to a planar wave, a spherical wave, or the like by a predetermined optical element (for example, pinhole aperture 11 to be described later). The multi-light beam 1b after the conversion has the light path changed by the light path changing section 2, and the intensity or the phase of the light beam changed by the pattern adjusting section 3X. Only the multi-light beam 1b at the position where the shutter is opened thus reaches the wafer WA. The multi-light beam 1b, which light path is changed by the light path changing section 2X, thus forms interference stripes on the wafer WA as the light beams (multi-light beams), which light path is changed, interfere.

FIG. 2 is a diagram showing a configuration example of the interference exposure apparatus according to the first embodiment. A schematic view of a cross-sectional configuration of an interference exposure apparatus 100A is shown here. The interference exposure apparatus 100A includes the pinhole aperture 11, a ring-shaped aperture 12A, a mask section 6A, and an incident region limiting section 13. A mechanism combining the pinhole aperture 11 and the ring-shaped aperture 12A corresponds to an incident angle filtering section, to be described later.

The pinhole aperture 11 converts an electromagnetic wave 1a from the light source to the multi-light beam 1b (spherical wave etc.) having coherency. The wavelength of the electromagnetic wave 1a from the light source may be a wavelength of one of ArF light, KrF light, or EUV light. For instance, the electromagnetic wave 1a of short wavelength is used when forming a fine pattern. The ring-shaped aperture 12A passes only the multi-light beam 1b from the pinhole aperture 11 having a predetermined incident angle.

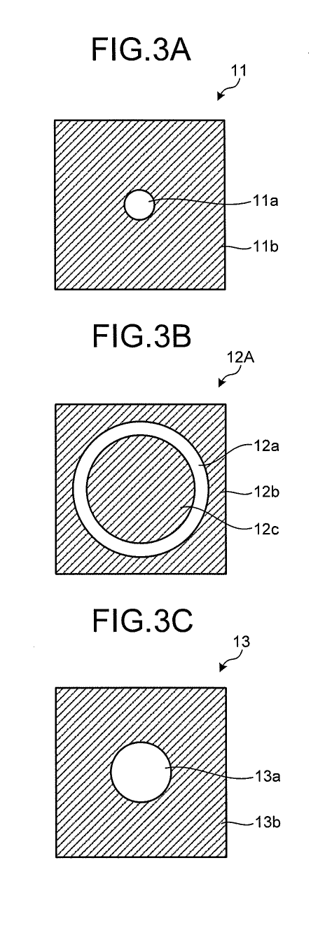

FIG. 3A to FIG. 3C are diagrams respectively showing one example of the pinhole aperture, the ring-shaped aperture, and the incident region limiting section. In FIG. 3A to FIG. 3C, a top view of the pinhole aperture 11, the ring-shaped aperture 12A, and the incident region limiting section 13 is shown.

The pinhole aperture 11 shown in FIG. 3A is configured by a schematic plate-like member, and includes a pinhole 11a having a predetermined radius at substantially the center. In the pinhole aperture 11, the pinhole 11a is formed with a transmissive material that transmits the electromagnetic wave 1a, and a peripheral portion 11b other than the pinhole 11a is formed with a non-transmissive material that does not transmit the electromagnetic wave 1a.

The ring-shaped aperture 12A shown in FIG. 3B is configured by a schematic plate-like member, and includes a ring-shaped transmitting portion 12a having a center coaxial with the pinhole 11a. In the ring-shaped aperture 12A, the transmitting portion 12a is formed with a transmissive material that transmits the multi-light beam 1b, and a peripheral portion 12b as well as a center portion 12c other than the transmitting portion 12a are formed with a non-transmissive material that does not transmit the multi-light beam 1b. The pinhole aperture 11 and the ring-shaped aperture 12A are configured such that the inner diameter of the transmitting portion 12a becomes greater than the radius of the pinhole 11a. The multi-light beam 1b having a predetermined incident angle of the multi-light beam 1b from the pinhole aperture 11 is exit from the ring-shaped aperture 12A.

The incident region limiting section 13 shown in FIG. 3C is configured by a schematic plate-like member, and includes a circular region 13a having a predetermined radius at the same center as the pinhole 11a. In the incident region limiting section 13, the circular region 13a is formed with a transmissive material that transmits the multi-light beam 1b, and a peripheral portion 13b other than the circular region 13a is formed with a non-transmissive material that does not transmit the multi-light beam 1b. The incident region limiting section 13 is configured such that the radius of the circular region 13a becomes greater than the radius of the pinhole 11a.

The mask section 6A corresponds to the light path changing section 2X and the pattern adjusting section 3X. The mask section 6X, for instance, is configured to include a micro-mirror array arranged in a ring shape, and a shutter. The micro-mirror array has a plurality of micro-mirrors arranged on an inner wall surface of the ring-shaped member having a predetermined height, where the multi-light beam 1b is reflected by the mirror surface of each micro-mirror.

The shutter is arranged in plurals so as to be lined in a ring shape at the lower part (wafer WA side) of the micro-mirror. Only the multi-light beam 1b at the position where the shutter is opened of the multi-light beam 1b reflected by the multi-light beam 1b reaches the wafer WA. The shutter may be arranged in plurals so as to be lined in a ring shape at the upper part (light source side) of the micro-mirror. In this case, only the multi-light beam 1b at the position where the shutter is opened is reflected by the micro-mirror array to reach the wafer WA.

The ring-shaped aperture 12A may be arranged between the mask section 6A and the incident region limiting section 13. The ring-shaped aperture 12A may also be arranged at both between the pinhole aperture 11 and the mask section 6A, and between the mask section 6A and the incident region limiting section 13. The arrangement of the ring-shaped aperture 12A may be omitted.

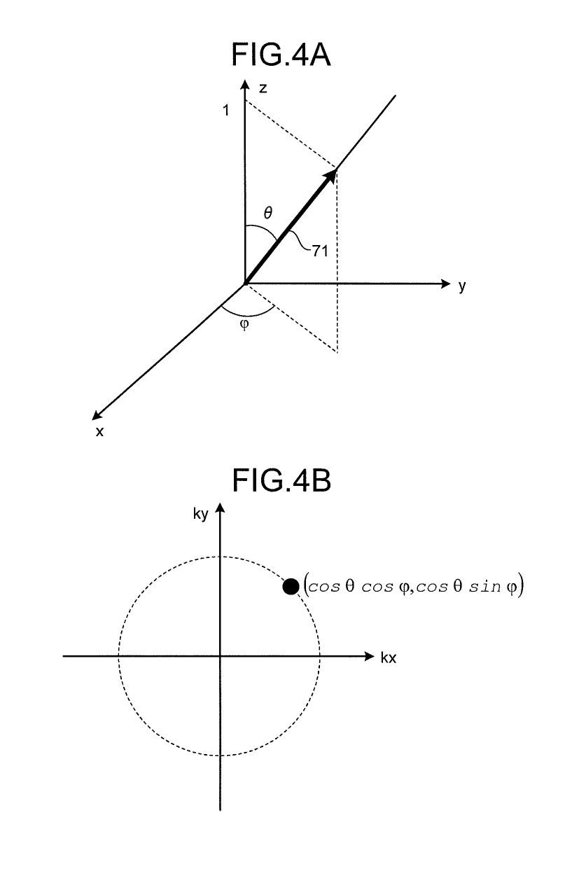

The definition of the beam coordinate system will now be described. FIG. 4A and FIG. 4B are diagrams describing the beam coordinate system. An xy plane shown in FIG. 4A is assumed as a wafer plane. The multi-light beam 1b entering the wafer WA in this case is shown with an incident beam 71. As shown in FIG. 4A, the incident angle of the incident beam 71 is defined with θ, φ. Here, φ is an angle formed by the incident beam 71 and the x axis, and θ is an angle formed by the incident beam 71 and the z axis. The incident direction vector of the incident beam 71 is expressed by equation (1).

[Equation 1]

\vec{k}=(cos θ cos φ, cos θ sin φ, {square root over (1−cos² θ))} (1)

The distance from the optical axis of the incident beam 71 is cos θ. The amplitude (include intensity information and phase information) at z=0 of the incident beam 71 is defined as a beam amplitude A₁. The incident direction of the incident beam 71 is expressed with a point coordinate (cos θ cos φ, cos θ sin θ) in a beam spatial coordinate system shown in FIG. 4B.

The pattern shape formed on the wafer WA when the multi-light beam 1b enters the wafer WA will now be considered. Assume a case where n (n is a natural number) multi-beams enter the wafer WA. If the incident direction vector and the amplitude of each beam are respectively defined as,

\vec{k}₁=Incident angle [Equation 2]

A₁=amplitude for l=1,2, . . . n [Equation 3]

the intensity I of the interference stripes formed on the wafer WA is expressed with the following equation (2) with respect to the wafer coordinate

\vec{x} [Equation 4]

$$\begin{matrix}[ Equation 5 ] & \\ \begin{matrix}I ( \vec{x} ) = {\vert {\sum }_{l = 1}^{n} {A}_{l} exp ( \frac{i {\vec{k}}_{l} \cdot \vec{x}}{λ} ) \vert}^{2} \\ = {\sum }_{l , m} {A}_{l} {A}_{m}^{*} exp ( \frac{i ( {\vec{k}}_{l} - {\vec{k}}_{m} ) \cdot \vec{x}}{λ} ) \\ = {\sum }_{l , m} {A}_{l} {A}_{m}^{*} exp ( \frac{i ( {\vec{k}}_{l} - {\vec{k}}_{m} ) \cdot ( x \hat{x} + y \hat{y} + z \hat{z} )}{λ} )\end{matrix} & ( 2 )\end{matrix}$$

### Assuming

\hat{z} [Equation 6]

is a unit vector in the z direction, the following equation (7) is obtained. Therefore, if the distance (cos θ) from the optical axis of each beam are all equal distance, the component that depends on the z direction does not exist in the intensity I of the interference stripe, and hence the focus margin degree with respect to the pattern formation can be sufficiently ensured.

$$\begin{matrix}[ Equation 7 ] & \\ \begin{matrix}( {\vec{k}}_{l} - {\vec{k}}_{m} ) \cdot \hat{z} = \sqrt{1 - {cos}^{2} {θ}_{1}} - \sqrt{1 - {cos}^{2} {θ}_{m}} \\ = 0 in case {θ}_{1} \\ = {θ}_{m}\end{matrix} & ( 3 )\end{matrix}$$

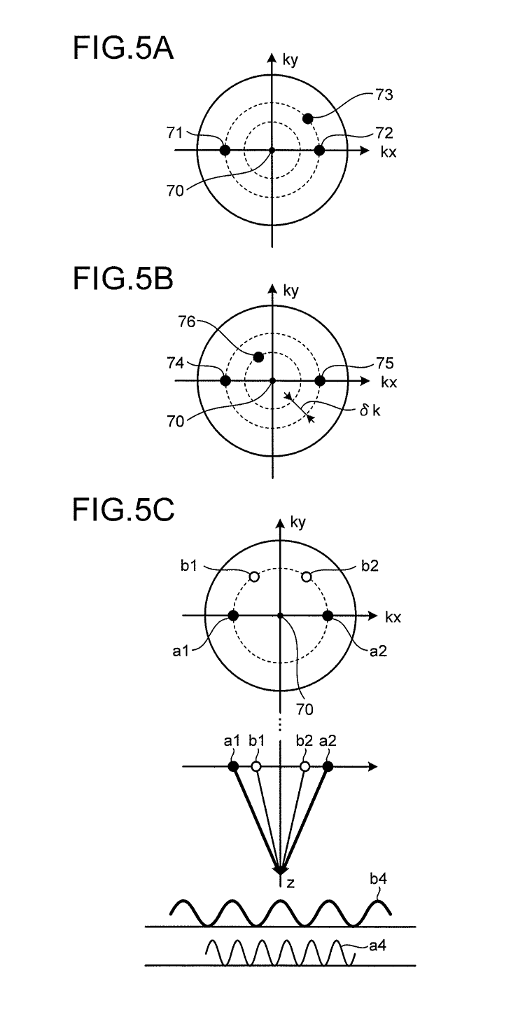

If the distance from the optical axis of each beam are not all equal distance, the pattern has a z direction dependency, and the focal depth becomes finite. FIG. 5A to FIG. 5C are diagrams describing the relationship of the distance from the optical axis of each beam and the DoF. In FIG. 5A to FIG. 5C, each beam is shown with a beam coordinate system. The beams 71 to 73 of when all the distances from the optical axis are equal distance are shown in FIG. 5A, and the beams 74 to 76 of when one of the distances from the optical axis is not equal distance is shown in FIG. 5B.

As shown in FIG. 5A, if the distances from the optical axis 70 of each beam 71 to 73 are all equal distance, the DoF becomes infinitely large. Furthermore, if the distance from the optical axis 70 of the beam 76 and the distance from the optical axis 70 of the beams 74, 75 of each beam 74 to 76 differ, the DoF becomes a finite size (DoF to 1/δk).

The type of pattern (optical image) formed by the interference of the multi-light beam will now be described. In FIG. 5C, the positions of the beams (light beam) a1, a2, b1, b2 at equal distance from the optical axis 70 on the beam coordinate system are shown.

FIG. 5C shows an aerial image (optical image) of the interference stripe pattern formed on the wafer WA in the case of two beams a1, a2 as an aerial image a4. An aerial image of the interference stripe pattern formed on the wafer WA in the case of two beams b1, b2 is shown as an aerial image b4. The pitch of the pattern corresponding to the aerial image a4 is inversely proportional to the distance between the beam a1 and the beam a2, and the pitch of the pattern corresponding to the aerial image b4 is inversely proportional to the distance between the beam b1 and the beam b2.

The light beams passing the positions at equal distance from the optical distance 70 have the same wave front phase change with respect to the defocus. Thus, the aerial images formed by the beams a1, a2, b1, b2 have an infinitely large DoF. Furthermore, an arbitrary pitch pattern greater than half the exposure wavelength can be formed by adjusting the distance between the plurality of light beams. Therefore, a complicated pattern can be formed on the wafer WA by using the multi-light beam. Therefore, the pattern variations of various pitches can be realized by using two light beams. A more complicated pattern can be formed by using three light beams or four light beams at equal distance from the optical axis 70.

For instance, when forming a pattern using four beams of beams a1, a2, b1, b2, an aerial image in which the aerial images generated for every combination of the beams a1, a2, b1, b2 are added is generated. Specifically, the aerial image by the interference of the beams a1, a2, the aerial image by the interference of the beams a1, b1, the aerial image by the interference of the beams a1, b2, the aerial image by the interference of the beams a2, b1, the aerial image by the interference of the beams a2, b2, and the aerial image by the interference of the beams b1, b2 are respectively added.

Thus, as the ring shaped aperture 12A passes only the beam having a predetermined incident angle with respect to the multi-light beam 1b, the focal depth (DoF) at the time of pattern transfer to the wafer WA can be widened.

In the present embodiment, the incident angle to the wafer WA can be held constant and the DoF can be sufficiently ensured since the light path changing section 2X is arranged substantially axisymmetrically with respect to the optical axis. Furthermore, a pattern of high degree of freedom can be formed without using a complicated projection optical system by controlling the pattern adjusting section 3X.

When forming the pattern on the wafer WA, the pattern may be formed in one shot by making one setting in the pattern adjusting section 3X, the pattern may be formed for every setting by making a plurality of settings in the pattern adjusting section 3X, or a more complicated pattern may be formed by combining the same. When making a plurality of settings in the pattern adjusting section 3X, the pattern forming position is set by variously changing the opening/closing of the shutter, for example.

Therefore, a pattern having a sufficient focal depth in micro units (substantially infinite focal depth) (depth of field) and having a high degree of freedom (substantially arbitrary pattern layout) can be formed through the use of the interference exposure apparatus 100X. The pattern can be formed in a mask-less manner using the interference exposure technique since patterning is carried out by controlling the controllable pattern adjusting section 3X. Therefore, the device configuration becomes smaller, and the patterning can be carried out at low cost and short TAT by an inexpensive lithography technique (desktop lithography).

Furthermore, as the interference exposure can be carried out in one exposure without using the mask, the exposure flow becomes simple. The device configuration also becomes simple as the pattern that does not have periodicity does not need to be transferred in the optical lithography exposure apparatus.

Therefore, according to the first embodiment, the interference exposure apparatus 100X can easily form various complicated patterns at low cost by including the light path changing section 2X and the pattern adjusting section 3X.

### Second Embodiment

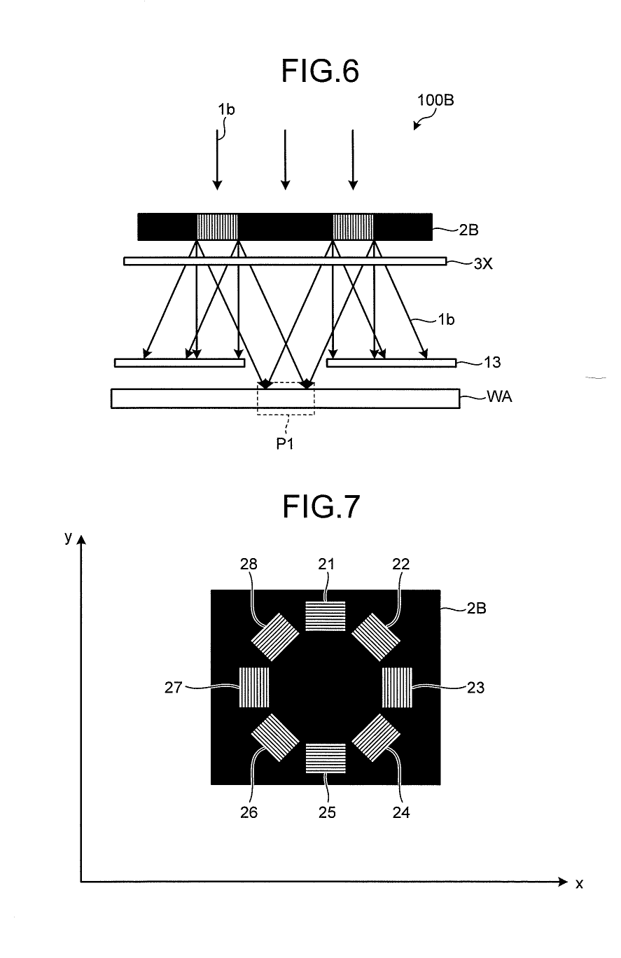

FIG. 6 is a diagram showing a configuration of an interference exposure apparatus according to a second embodiment. A schematic diagram of a cross-sectional configuration of an interference exposure apparatus 100B is shown. The configuring elements for achieving the same functions as the interference exposure apparatus 100X of the first embodiment of each configuring element of FIG. 6 are denoted with the same numbers to omit redundant description.

The interference exposure apparatus 100B includes a diffraction grating 2B as the light path changing section 2X. According to such configuration, the multi-light beam 1b converted to a planar wave, a spherical wave, or the like is diffracted by the diffraction grating 2B, and has the intensity or the phase of the light beam changed by the pattern adjusting section 3X. Only the multi-light beam 1b that passed the pattern adjusting section 3X and the incident region limiting section 13 reaches the wafer WA. An interference pattern P1 by the multi-light beam 1b is thereby formed on the wafer WA.

FIG. 7 is a top view showing a configuration of the diffraction grating. The diffraction grating 2B is configured by a substantially plate-like member, where a plurality of diffraction grating patterns is formed to be lined to a substantially ring shape at positions equal distance from the center portion. A case where the diffraction grating patterns 21 to 28 are formed for the diffraction grating pattern is shown. The diffraction grating pattern 21 is arranged at a position of twelve o'clock of the ring shape (circumference), and the diffraction grating patterns 22, 23, 24, 25, 26, 27, 28 are lined in such order in the clockwise direction. The diffraction grating patterns 23, 25, 27 are respectively arranged at positions of three o'clock, six o'clock, and nine o'clock, and the diffraction grating pattern 21 is arranged between the diffraction grating pattern 22 and the diffraction grating pattern 28.

Each diffraction grating pattern 21 to 28 is configured by a plurality of slit patterns. In the diffraction grating 2B, each diffraction grating pattern 21 to 28 is arranged so that the longitudinal direction of each slit pattern is the tangent direction of the ring shape. For instance, the diffraction grating pattern 21 is arranged in the diffraction grating 2B so that a line connecting the center portion of the ring shape and the center portion of the diffraction grating pattern 21 and the longitudinal direction of the diffraction grating pattern 21 become parallel. The longitudinal direction of the diffraction grating patterns 21, 25 is the x direction, and the longitudinal direction of the diffraction grating patterns 23, 27 is the y direction.

When forming the pattern on the wafer WA, only the light beam at the position corresponding to the pattern shape to form (also include information on dimension) is exit from the pattern adjusting section 3X. For instance, if the pattern adjusting section 3 is a shutter, the desired pattern can be formed by closing the shutter at the position (diffraction grating pattern) corresponding to the pattern shape to form. The position to close the shutter is determined based on the information obtained by Fourier transformation by Fourier transforming the pattern shape to form.

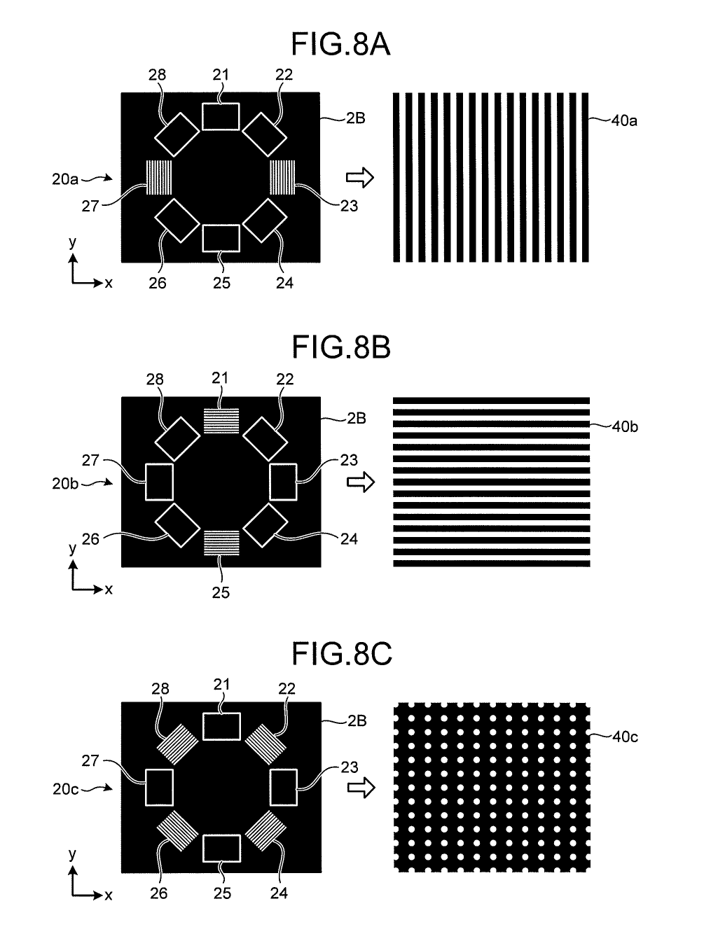

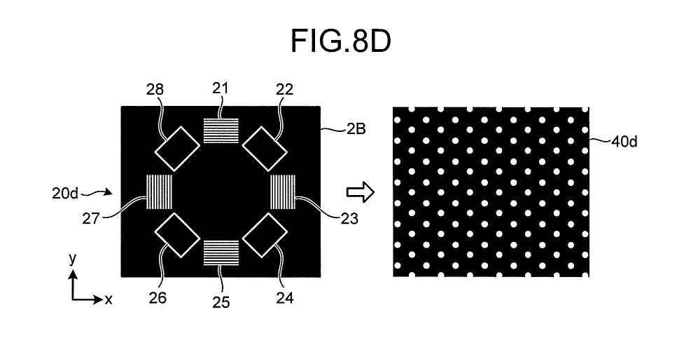

FIG. 8A to FIG. 8D are diagrams showing a relationship of a light shielding section and an imaging pattern. In FIG. 8A to FIG. 8D, a relationship example of the open/close state of the light shielding section and the imaging pattern on the wafer WA is shown. In FIG. 8A, a state 20a in which the light shielding section (e.g., shutter) at the lower part of the diffraction grating patterns 21, 22, 24, 25, 26, 28 of the diffraction grating patterns 21 to 28 is closed, and the light shielding section at the lower part of the diffraction grating patterns 23, 27 is opened is shown. When the exposure is carried out on the wafer WA in such a state, a plurality of line & space patterns (imaging pattern 40a) lined parallel to the longitudinal direction (y direction) of the slits of the diffraction grating patterns 23, 27 is generated on the wafer WA.

In FIG. 8B, a state 20b in which the light shielding section (e.g., shutter) at the lower part of the diffraction grating patterns 22 to 24, and 26 to 28 of the diffraction grating patterns 21 to 28 is closed, and the light shielding section at the lower part of the diffraction grating patterns 21, 25 is opened is shown. When the exposure is carried out on the wafer WA in such a state, a plurality of line & space patterns (imaging pattern 40b) lined parallel to the longitudinal direction (x direction) of the slits of the diffraction grating patterns 21, 25 is generated on the wafer WA.

In FIG. 8C, a state 20c in which the light shielding section (e.g., shutter) at the lower part of the diffraction grating patterns 21, 23, 25, 27 of the diffraction grating patterns 21 to 28 is closed, and the light shielding section at the lower part of the diffraction grating patterns 22, 24, 26, 28 is opened is shown. When the exposure is carried out on the wafer WA in such a state, an imaging pattern 40c in which a plurality of schematically circular patterns (circular pattern) is lined at a predetermined interval is generated on the wafer WA. The circular patterns configuring the imaging pattern 40c are arranged such that the circular patterns are lined in a grating form.

In FIG. 8D, a state 20d in which the light shielding section at the lower part of the diffraction grating patterns 22, 24, 26, 28 of the diffraction grating patterns 21 to 28 is closed, and the light shielding section at the lower part of the diffraction grating patterns 21, 23, 25, 27 is opened is shown. When the exposure is carried out on the wafer WA in such a state, an imaging pattern 40d in which a plurality of schematically circular patterns (circular pattern) is lined at a predetermined interval is generated on the wafer WA. The circular patterns configuring the imaging pattern 40d are arranged such that the circular patterns are lined in an oblique grating form.

Therefore, the wafer pattern of various pattern variations can be formed by variously changing the light shielding section arranged at the lower part of the diffraction grating 2B.

The diffraction grating pattern configuring the diffraction grating 2B is not limited to eight, and may be nine or more. The diffraction grating pattern configuring the diffraction grating 2B may be between three and seven.

Thus, according to the second embodiment, the interference exposure apparatus 100B can easily form various complicated patterns at low cost by including the diffraction grating 2B as the light path changing section 2X.

### Third Embodiment

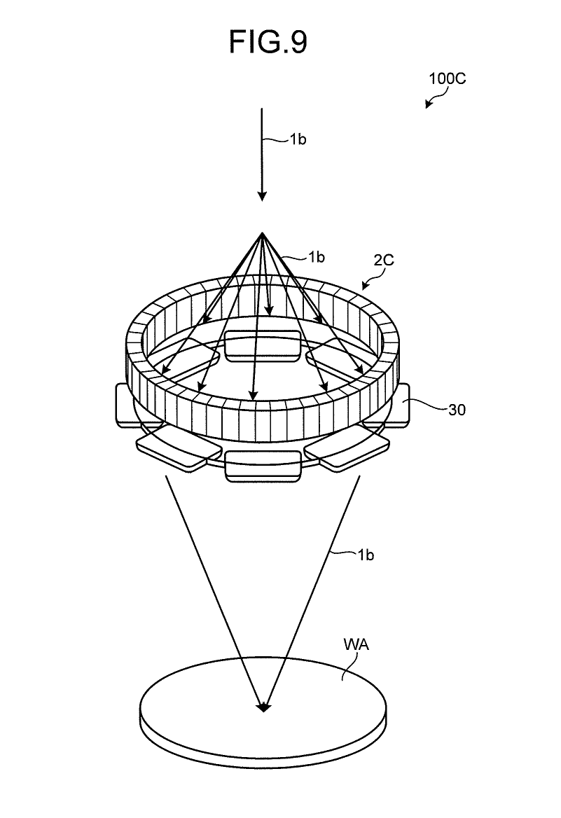

A third embodiment of the present invention will now be described using FIG. 9 to FIG. 11B. In the third embodiment, a micro-mirror ring is used as the light path changing section 2X.

FIG. 9 is a diagram showing a configuration of a micro-mirror ring. In FIG. 9, a perspective view of an interference exposure apparatus 100C including a micro-mirror ring 2C is shown. In FIG. 9, the illustration of the pinhole aperture 11, the ring-shaped aperture 12A, and the like is omitted.

In the micro-mirror ring 2C, each mirror is arranged such that a plurality of mirror surfaces is facing the inner side in the cylindrical inner wall surface. In other words, in the micro-mirror ring 2C, a plurality of mirrors is closely arranged on the cylindrical inner wall surface so that the ring-shaped inner side becomes the mirror surface. The interference exposure apparatus 100C has the pattern adjusting section 3X configured by a plurality of shutter sections 30.

The multi-light beam 1b is emitted from the ring-shaped aperture 12A to the micro-mirror ring 2C. The multi-light beam 1b emitted to the mirror surface of the micro-mirror ring 2C is reflected by the mirror surface. Thus, the multi-light beam 1b is transmitted towards the shutter section 30 with the light path direction and the light path length changed by the mirror surface. Only the multi-light beam 1b that passed the shutter section 30 reaches the wafer WA.

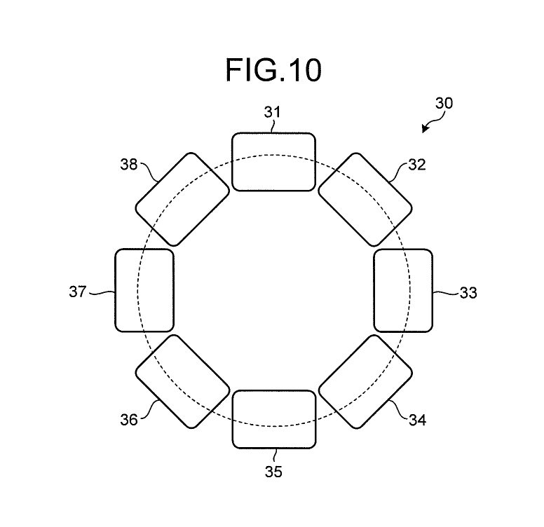

FIG. 10 is a top view showing a configuration example of the shutter section. Each shutter section 30 has a flat plate shape in which at least one main surface is the light shielding section, and is arranged at the lower part of the pattern adjusting section 3X. When the shutter section 30 is closed, the multi-light beam 1b reflected by the mirror surface at the upper part of the shutter section 30 is shielded by the closed shutter section 30. When the shutter section 30 is opened, the multi-light beam 1b reflected by the mirror surface at the upper part of the shutter section 30 is passed without being shielded by the shutter section 30.

The shutter section 30 includes a plurality of shutters configured by a schematic plate-like member, where each shutter is arranged to line in a substantially ring shape at positions equal distance from the center portion. A case where shutters 31 to 38 are formed for the shutter is shown. The shutter 31 is arranged at a position of twelve o'clock of the ring shape (circumference), and the shutters 32, 33, 34, 35, 36, 37, 38 are lined in such order in the clockwise direction. The shutters 33, 35, 37 are respectively arranged at positions of three o'clock, six o'clock, and nine o'clock, and the shutter 31 is arranged between the shutter 32 and the shutter 38.

The shutter section 30 is arranged to form a ring shape similar to the micro-mirror ring 2C at the lower side of the micro-mirror ring 2C. The shutter at a predetermined position is closed and the other shutters are opened based on the pattern shape to form on the wafer WA. In other words, when forming the pattern on the wafer WA, only the light beam at the position corresponding to the pattern shape to form is emitted from the shutter section 30. As will be described in a fifth embodiment and a sixth embodiment below, a polarization section or a phase adjuster may be arranged at each shutter position so that the intensity or the phase of each light beam can be changed. According to such configuration, the intensity and the phase of each light beam can be changed for every shutter 31 to 38.

Thus, the multi-light beam 1b that passed the position of the opened shutter section 30 is transmitted to the wafer WA thus interfering on the wafer WA, whereby a pattern corresponding to the open/close state of the shutter section 30 is formed on the wafer WA.

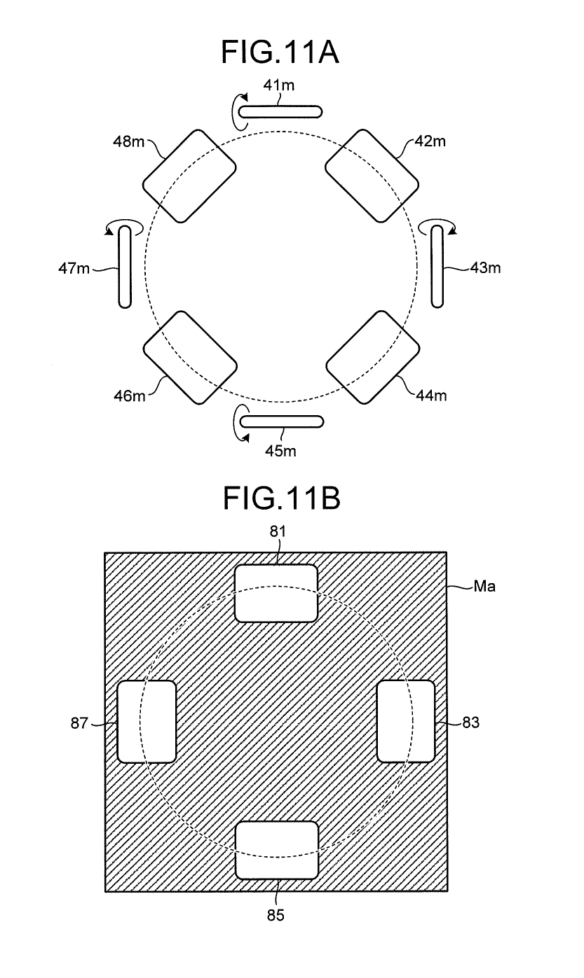

A movable micro-mirror array or a mask may be arranged in place of the freely openable/closable shutter section 30. In this case, the micro-mirror or the mask is arranged at the position of each shutter 31 to 38. FIG. 11A and FIG. 11B are diagrams showing another configuration example of the pattern adjusting section.

FIG. 11A is a top view of the micro-mirror array serving as the pattern adjusting section 3X. The micro-mirrors 41m to 48m configuring the micro-mirror array have a flat plate shape in which the upper surface side is the mirror surface, and are arranged at the same positions as the shutters 31 to 38. When the mirror surface is closed by a predetermined angle, the multi-light beam 1b is reflected by the mirror surface and exit to the outside of the micro-mirror. The multi-light beam 1b passes through without being reflected by the mirror surface by completely opening the mirror surface.

In FIG. 11A, a state in which the micro-mirrors 41m, 43m, 45m, 47m are completely opened and the micro-mirrors 42m, 44m, 46m, 48m are closed by a predetermined angle is shown. In this state, the multi-light beam 1b entering the micro-mirrors 41m, 43m, 45m, 47m is transmitted to the downstream side of the micro-mirror array. The multi-light beam 1b entering the micro-mirrors 42m, 44m, 46m, 48m is reflected by the micro-mirrors 42m, 44m, 46m, 48m and transmitted towards the outer peripheral part of the micro-mirror array.

FIG. 11B is a top view of a mask Ma serving as the pattern adjusting section 3X. The mask Ma is configured by a schematically flat plate like member, where a light shielding body is arranged on at least one main surface. The mask Ma is opened only at the area desired to pass the multi-light beam 1b. The opening of the mask Ma is determined based on the pattern shape to form. For instance, the mask Ma includes openings 81, 83, 85, 87. The openings 81, 83, 85, 87 correspond to the positions of the shutters 31, 33, 35, 37 (micro-mirrors 41m, 43m, 45m, 47m).

According to such configuration, the multi-light beam 1b entering the openings 81, 83, 85, 87 is transmitted to the downstream side of the mask Ma. The multi-light beam 1b entering other than the openings 81, 83, 85, 87 is shielded by the mask Ma.

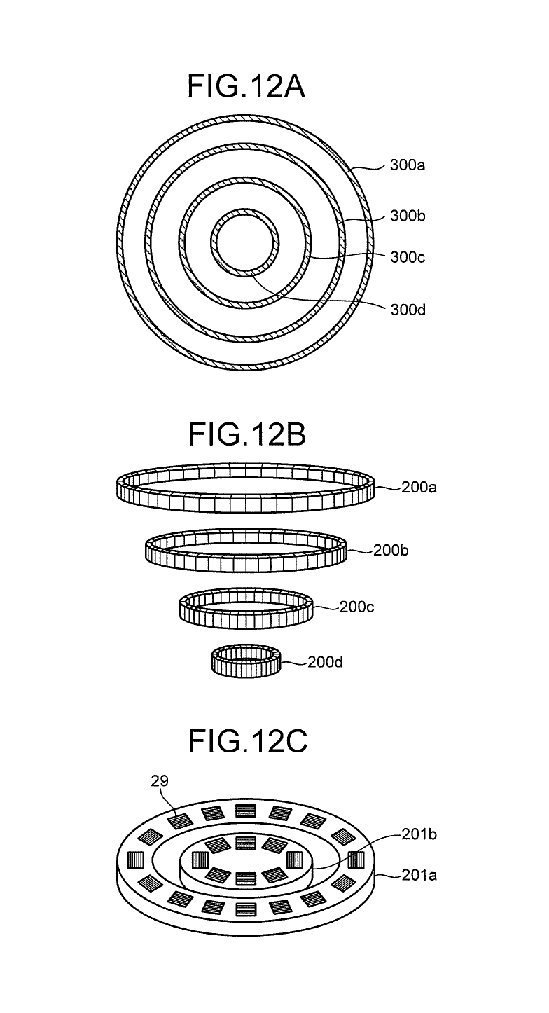

A plurality of light path changing sections 2X having different ring radius may be arranged in the interference exposure apparatus 100C. FIG. 12A to FIG. 12C are top views showing the configuration of a plurality of light path changing sections. In FIG. 12A, a case in which the light path changing section 2X is configured by light path changing sections 300a to 300d is shown.

The light path changing sections 300a to 300d are respectively a device for changing the light path direction and the light path length of the multi-light beam 1b, and respectively have a configuration of being substantially axisymmetrically with respect to the optical axis of the multi-light beam 1b. The light path changing directions 300a to 300d are arranged such that the respective centers are coaxial, and form a ring shape having different radius. The outer diameter of the light path changing section 300b is smaller than the inner diameter of the light path changing section 300a, and the outer system of the light path changing section 300c is smaller than the inner diameter of the light path changing section 300b. The outer system of the light path changing section 300d is smaller than the inner diameter of the light path changing section 300c.

A shutter, or the like is arranged at each lower part of the light path changing sections 300a to 300d. The light path changing section 2X is not limited to being configured by four rings, and may be configured by two, three, or five or more rings.

FIG. 12B shows a configuration diagram of when the light path changing section 2X is configured by micro-mirror rings 200a to 200d. A plurality of micro-mirror rings 200a to 200d having different ring radius are arranged so that the respective ring-shaped centers are coaxial. The micro-mirror rings 200a to 200d are arranged in the order of the light path changing section 300a, the light path changing section 300b, the light path changing section 300c, and the light path changing section 300d (order of large radius) from the upstream side to the downstream side of the multi-light beam 1b.

FIG. 12C shows a configuration diagram of when the light path changing section 2X is configured by diffraction gratings 201a, 201b. The diffraction gratings 201a, 201b are respectively configured with a plurality of diffraction grating patterns 29 lined to a ring shape. The ring diameter of the diffraction grating pattern 29 arranged on the diffraction grating 201a is greater than the ring diameter of the diffraction grating pattern 29 arranged on the diffraction grating 201b. The diffraction gratings 201a, 201b are arranged so that the respective ring-shaped centers are coaxial.

The diffraction gratings 201a, 201b are arranged on the same plane, which plane is directed in a direction substantially perpendicular to the multi-light beam 1b. The diffraction gratings 201a, 201b have a diffraction grating pitch corresponding to the radius of the ring in which the diffraction grating patterns 29 are lined. Since the ring diameter of the diffraction grating pattern 29 is larger in the diffraction grating 201a than in the diffraction grating 201b, the diffraction grating pitch of the diffraction grating 201a is formed to be smaller than the diffraction grating pitch of the diffraction grating 201b. A shutter, or the like is arranged at each lower part of the diffraction gratings 201a, 201b.

Therefore, a flexible pattern exposure process can be carried out by arranging a plurality of micro-mirror rings 200a to 200d having a different radius or the diffraction gratings 201a, 201b.

Each light beam from the micro-mirror rings 200a to 200d may be prevented from entering the wafer WA simultaneously. For instance, a freely openable/closable light shielding section (shutter etc.) corresponding to the shape of the micro-mirror rings 200a to 200d may be arranged at the upper part or the lower part of the micro-mirror rings 200a to 200d. The multi-light beam 1b may be entered in order with respect to the micro-mirror rings 200a to 200d.

When entering the multi-light beam 1b to the wafer WA from one micro-mirror ring, the multi-light beam 1b is not entered to the wafer WA from the other micro-mirror rings. For instance, when entering the multi-light beam 1B to the wafer WA from the micro-mirror ring 200a, the multi-light beam 1b is not entered to the wafer WA from the micro-mirror rings 200b to 200d. In this case as well, only the shutter at the position corresponding to the pattern shape to form is opened in the shutter arranged at the lower part of the micro-mirror ring 200a.

Similarly, when entering the multi-light beam 1b to the wafer WA from one diffraction grating, the multi-light beam 1b is not entered to the wafer WA from the other diffraction grating. When using the diffraction grating as well, the multi-light beam 1b is entered in order with respect to the diffraction gratings 201a, 201b. Thus, the DoF margin can be sufficiently ensured by not entering each light beam to the wafer WA simultaneously from the micro-mirror rings 200a to 200d (diffraction gratings 201a, 201b).

Assuming the diffraction grating pitches of the diffraction gratings 201a, 201b are the same diffraction grating pitch, the diffraction grating 201a and the diffraction grating 201b may be arranged on different planes. In this case, the diffraction gratings 201a, 201b are arranged on a plane having a height corresponding to the ring diameter of the diffraction grating pattern 29. The light path changing section 2X is not limited to being configured by two rings such as the diffraction gratings 201a, 201b, and may be configured by three or more rings.

Thus, according to the third embodiment, the interference exposure apparatus 100C can easily form various complicated patterns at low cost by including the micro-mirror ring 2C as the light path changing section 2X.

### Fourth Embodiment

A fourth embodiment of the present invention will now be described using FIG. 13. In the fourth embodiment, a prism is used as the light path changing section 2X.

FIG. 13 is a diagram showing a configuration of the light path changing section according to the fourth embodiment. A prism 2D serving as the light path changing section 2X has a circular cone shape. A distal end portion including the vertex portion of the circular cone shaped prism 2D is configured by a reflecting member 49 adapted to reflect the multi-light beam 1b. The reflecting member 49 prevents the entering of the multi-light beam 1b by reflecting the multi-light beam 1b two or more times in the prism 2D. With the height of the reflecting member 49 greater than or equal to a predetermined value, the multi-light beam 1b enters from the lower part side of the prism 2D so as to be reflected only once at the prism 2D and exit to the outside of the prism 2D.

In the light path changing section 2X, the shutter section 30 is arranged on an upper part side (light source side) of the prism 2D. According to such configuration, the multi-light beam 1b that passed the shutter section 30 advances into the prism 2D and has the advancing direction of the light beam changed. The multi-light beam 1b is thereby collected in the prism 2D and irradiated on the wafer WA.

The prism 2D may have a polyangular cone shape. In this case, the prism 2D may have a shape corresponding to the number of shutters. For instance, if the number of shutters is m (m is a natural number), the shape of the prism may be m-angular cone shape.

Thus, according to the fourth embodiment, the interference exposure apparatus 100X can easily form various complicated patterns at low cost by including the prism 2D as the light path changing section 2X.

### Fifth Embodiment

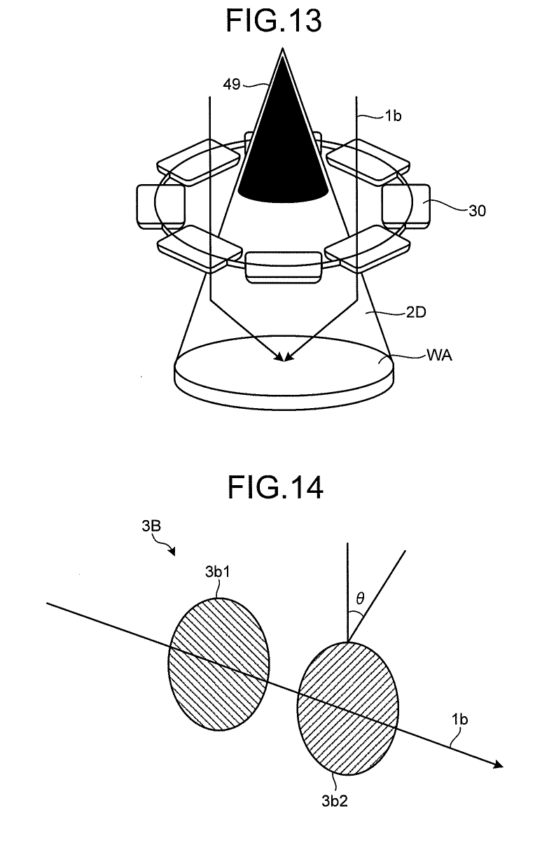

A fifth embodiment of the present invention will be described using FIG. 14. In the fifth embodiment, a polarization section including two polarization plates is used as the pattern adjusting section 3X.

FIG. 14 is a perspective view showing a configuration of a polarization section according to the fifth embodiment. A polarization section 3B includes a polarization plate 3b1, which is a first polarization plate, and a movable polarization plate 3b2, which is a second polarization plate. The polarization plates 3b1, 3b2 are configured from schematic plate-like members, and are arranged on the light path of the multi-light beam 1b such that the main surface is perpendicular to the optical axis of the multi-light beam 1b.

A set of polarization section 3B including the polarization plates 3b1, 3b2 is arranged in place of one shutter. Thus, as shown in FIG. 13, eight sets of polarization sections 3B are arranged when arranging the polarization section 3B in place of eight shutters.

The polarization plate 3b1 is arranged on the upstream side (light source side) of the polarization plate 3b2. The deflection angle of the polarization plate 3b2 is rotated so as to become a predetermined angle (θ) with respect to the deflection angle of the polarization plate 3b1.

The multi-light beam 1b transmitted from the light path changing section 2X is polarized to a light of a predetermined angle by the polarization plate 3b1, and then further polarized to a light of a predetermined angle (θ) by the polarization plate 3b2. The intensity of the multi-light beam 1b is thereby adjusted. The polarization plate 3b1 may be movable.

Thus, according to the fifth embodiment, the interference exposure apparatus 100X can easily form various complicated patterns at low cost by including two polarization plates 3b1, 3b2 as the pattern adjusting section 3X.

### Sixth Embodiment

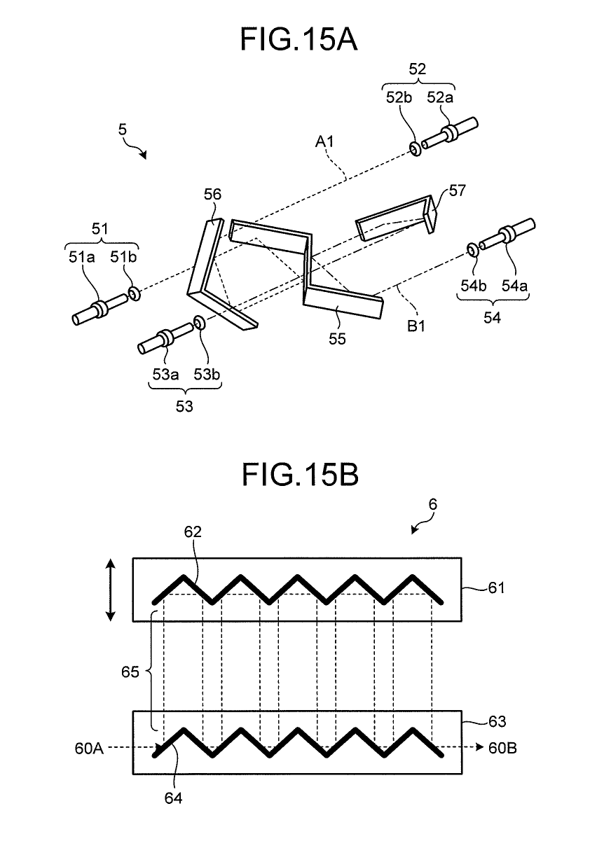

A sixth embodiment of the present invention will now be described using FIG. 15A and FIG. 15B. In the sixth embodiment, a phase adjuster is used as the pattern adjusting section 3.

FIG. 15A and FIG. 15B are diagrams showing a configuration of a phase adjuster according to the sixth embodiment. A phase adjuster 5 shown in FIG. 15A includes collimator units 51 to 54, where a pair of inputs is formed with the collimator units 51, 53 and a pair of outputs is formed with the collimator units 52, 54.

The collimator unit 51 is configured by an optical fiber terminal 51a and a collimator lens 51b, and the collimator unit 53 is configured by an optical fiber terminal 53a and a collimator lens 53b.

The collimator unit 52 is configured by an optical fiber terminal 52a and a collimator lens 52b, and the collimator unit 54 is configured by an optical fiber terminal 54a and a collimator lens 54b.

Two fixing mirrors 56, 57 having an L-shaped cross-section and a movable mirror 55 having a crank-shaped cross-section are interposed between the input and the output (between collimator units 51, 53 and collimator units 52, 54).

The fixing mirrors 56, 57 are respectively formed by bending a schematic square flat plate once so that the cross-section becomes an L-shape of a vertex angle. The movable mirror 55 is formed by bending a schematic square flat plate twice so that the cross-section becomes a crank shape. The inner surfaces of the fixing mirrors 56, 57 and the movable mirror 55 are formed with a mirror surface having high reflectance by coating, and the like.

The fixing mirror 56 transmits the light from the collimator unit 51 to the collimator unit 52, and the fixing mirror 57 transmits the light from the collimator unit 53 to the collimator unit 54. The movable mirror 55 is configured to be movable along the optical axis direction between the fixing mirror 56 and the fixing mirror 57.

In the phase adjuster 5, a light path through which the light is propagated in the order of the collimator unit 51, the movable mirror 55, the fixing mirror 56, and the collimator unit 52 is a light path A1. A light path through which the light is propagated in the order of the collimator unit 53, the fixing mirror 57, the movable mirror 55, and the collimator unit 54 is a light path B1.

Therefore, the light entered from the collimator unit 51 is reflected by the fixing mirror 56 and the movable mirror 55 to be exit from the collimator unit 52, and the light entered from the collimator unit 53 is reflected by the fixing mirror 57 and the movable mirror 55 to be exit from the collimator unit 54.

Specifically, in the light path A1, the light entered from the collimator unit 51 is reflected twice at the reflection surface for the light path A1 of the movable mirror 55 so that the direction of the optical axis is turned 180 degrees. The light returned at the movable mirror 55 is reflected twice at the fixing mirror 56 so that the direction of the optical axis is again turned 180 degrees to be input to the collimator unit 52. The surface formed by the reflected light path in the fixing mirror 56 is arranged to tilt +45 degrees with respect to a surface (horizontal surface) formed by the reflected light path in the movable mirror 55. The light turned by the fixing mirror 56 also has the optical axis differing in the height direction at the same time, and thus can be input to the collimator unit 52 without interfering with the movable mirror 55.

In the light path B1, the light entered from the collimator unit 53 is reflected twice at the fixing mirror 57 so that the direction of the optical axis is turned 180 degrees in the horizontal direction. The light turned at the fixing mirror 57 is reflected by the movable mirror 55 so that the direction of the optical axis is again turned 180 degrees to be input to the collimator unit 54. The surface formed by the reflected light path in the fixing mirror 57 is arranged to tilt −45 degrees with respect to the horizontal surface. The light turned by the fixing mirror 57 also has the optical axis differing in the height direction at the same time, and thus can be input to the collimator unit 54 without interfering with the movable mirror 55.

In the phase adjuster 5, the distance of the light path A1 and the light path B1 changes as the movable mirror 55 moves along the optical axis direction between the fixing mirror 56 and the fixing mirror 57, whereby the phase of the multi-light beam 1b is modulated.

A phase adjuster 6 shown in FIG. 15B includes a movable portion 61 and a fixing portion 63. A mirror 62 bent at a predetermined angle is arranged on the movable portion 61, and a mirror 64 is arranged on the fixing portion 63 so as to face the mirror 62. A retro-reflector is configured by the mirror 62. According to such configuration, a plurality of pairs of light paths 65 formed by the mirror 62 and the mirror 64 all become parallel.

In the phase adjuster 6, the light entering from 60A on the fixing portion 63 side exits from 60B on the fixing portion 63 side via the light path 65. In this case, the movable portion 61 is moved substantially parallel to the direction of the light path 65. A motor drive stage moved by a motor that can respond/be driven at high speed may be used or a piezo drive stage moved by a piezo element that can respond/be driven at high speed may be used for the movement of the movable portion 61. In the phase adjuster 6, the distance of the light path 65 changes by moving the movable portion 61 in a direction same as the direction of the light path 65, whereby the phase of the multi-light beam 1b is modulated.

Thus, according to the sixth embodiment, the interference exposure apparatus 100X can easily form various complicated patterns at low cost by including the phase adjuster 5 or the phase adjuster 6 as the pattern adjusting section 3X.

### Seventh Embodiment

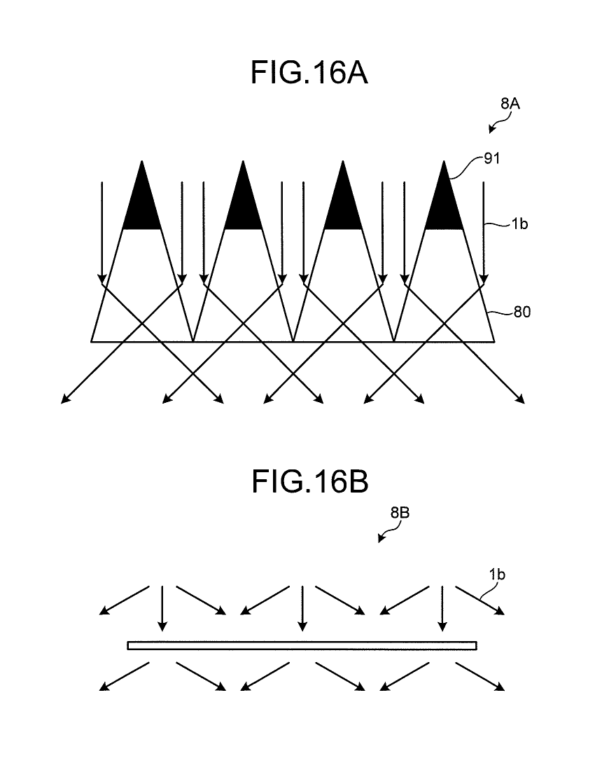

A seventh embodiment of the present invention will now be described using FIG. 16A and FIG. 16B. In the first embodiment described above, a case in which the incident angle filtering section is the pinhole aperture 11 and the ring-shaped aperture 12A has been described. In the seventh embodiment, a circular cone shaped prism or a Fabry-Perot elaton is used as the incident angle filtering section.

FIG. 16A and FIG. 16B are diagrams showing a configuration of an incident angle filtering section according to a seventh embodiment. FIG. 16A shows a cross-sectional configuration of an incident angle filtering section 8A configured using a plurality of circular cone shaped prisms 80.

The incident angle filtering section 8A is configured with the plurality of circular cone shaped prisms 80 having substantially the same shape arranged. The circular cone shaped prism 80 has a configuration similar to the prism 2D. In the incident angle filtering section 8A, the circular cone shaped prisms 80 are arranged such that the bottom surface of each circular cone shaped prism 80 is lined on the same plane. A plane in which the bottom surface of each circular cone shaped prism 80 is lined is directed in a perpendicular direction with respect to the multi-light beam 1b.

A distal end portion including the vertex portion of the circular cone shaped prism 80 is configured by a reflecting member 91 for reflecting the multi-light beam 1b. The reflecting member 91 has a configuration similar to the reflecting member 49.

According to such configuration, the multi-light beam 1b that entered the incident angle filtering section 8A is exit towards the wafer WA as an exit light of a predetermined angle. Thus, the multi-light beam 1b enters the wafer WA at a predetermined incident angle. Therefore, the DoF widens by filtering the incident angle of the multi-light beam 1b to the wafer WA at the incident angle filtering section 8A.

The incident angle filtering section 8A may be arranged at any position as long as it is a position before the multi-light beam 1b enters the wafer WA. A polyangular circular cone shaped prism may be used in place of the circular cone shaped prism 80. When using the polyangular circular cone shaped prism, a plurality of circular cone shaped prisms 80 is arranged in the same plane similar to the circular cone shaped prism 80. A light shielding plate for shielding the passing of the light and the like may be arranged at the upper part side or the lower part side of the gap with respect to the gap between the circular cone shaped prism 80 and the circular cone shaped prism 80. The incident angle filtering section 8A may be configured by one circular cone shaped prism 80.

FIG. 16B shows an incident angle filtering section 8B configured using the Fabry-Perot elaton. The incident angle filtering section 8B is the Fabry-Perot elaton, where the multi-light beam 1b that entered the incident angle filtering section 8B is exit towards the wafer WA as the multi-light beam 1b in which the beam shape is a cone shape (circular cone shape). Thus, the multi-light beam 1b spreads along the generatrix from the vertex of the circular cone. The multi-light beam 1b enters the wafer WA at a predetermined incident angle. Therefore, in the incident angle filtering section 8B, the DoF widens by filtering the incident angle of the multi-light beam 1b to the wafer WA. The incident angle filtering section 8B may be arranged at any position as long as it is a position before the multi-light beam 1b enters the wafer WA.

Thus, according to the seventh embodiment, the interference exposure apparatus 100X can easily widen the DoF at low cost by including the circular cone shaped prism or the Fabry-Perot elaton as the incident angle filtering sections 8A, 8B.

The exposure to the wafer WA by the interference and exposure apparatus 100X is carried out, for example, on a predetermined layer of the wafer process. In this case, the adjustment of the light path changing section 2X and the pattern adjusting section 3X is carried out for every pattern desired to be formed on the wafer WA. A film forming process is carried out by a predetermined film forming device on the wafer WA. When carrying out the lithography process on the wafer WA, a resist is applied on the wafer WA. The interference exposure apparatus 100X carries out interference exposure on the wafer WA applied with the resist, where the wafer WA is thereafter developed and the resist pattern is formed on the wafer WA. The lower layer side of the wafer WA is etched with the resist pattern as the mask. Thus, an actual pattern corresponding to the resist pattern is formed on the wafer WA. When manufacturing the semiconductor device (semiconductor integrated circuit), the film forming process, the exposure process, the developing process, the etching process, and the like are repeated for every layer.

Therefore, according to the first to seventh embodiments, various patterns can be easily formed on the wafer at low cost.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An interference exposure apparatus comprising:
a light path changing section in which a changing element adapted to change a light path direction and a light path length of a plurality of light beams with respect to the plurality of light beams having coherency with respect to each other is arranged substantially axisymmetrically; and
an adjusting section configured to adjust one part of the light beam entering a substrate by intensity changing or phase changing one part of the light beam corresponding to a pattern shape to form on the substrate, wherein
a light beam exit from the light path changing section and the adjusting section is interfered on the substrate to carry out an interference exposure on the substrate.

2. The interference exposure apparatus according to claim 1, wherein the light path changing section is configured to include a diffraction grating arranged in a ring-shape in a plane substantially perpendicular to the light beam.

3. The interference exposure apparatus according to claim 1, wherein
the light path changing section is configured to include a plurality of micro-mirrors, and
the micro-mirrors are arranged in a ring-shape to configure a tubular inner wall surface by each mirror surface.

4. The interference exposure apparatus according to claim 1, wherein the light path changing section is configured to include a first prism of a circular cone shape and a second prism of a polyangular cone shape.

5. The interference exposure apparatus according to claim 1, further comprising a filtering section configured to filter an angle at which the light beam enters the substrate.

6. The interference exposure apparatus according to claim 5, wherein the filtering section is configured to include one of an aperture, a Fabry-Perot interference system, a third prism having a circular cone shape, and a fourth prism having a polyangular cone shape.

7. The interference exposure apparatus according to claim 2, wherein the light path changing section includes a plurality of rings in which the diffraction gratings are arranged, each ring being concentrically arranged in plurals.

8. The interference exposure apparatus according to claim 3, wherein the light path changing section includes a plurality of rings in which the micro-mirrors are arranged, each ring being concentrically arranged in plurals.

9. The interference exposure apparatus according to claim 1, wherein the adjusting section is one of two polarization plates, a freely openable/closable shutter, a movable micro-mirror array, and a mask, or a combination thereof.

10. The interference exposure apparatus according to claim 4, wherein the first or second prism has a distal end portion including a vertex portion configured by a reflection member configured to reflect the plurality of light beams.

11. An interference exposure method comprising the steps of:
changing a light path direction and a light path length of a plurality of light beams with a light path changing section in which a changing element adapted to change the light path direction and the light path length of the plurality of light beams having coherency with respect to each other is arranged substantially axisymmetrically;
adjusting one part of the light beam with an adjusting section configured to adjust one part of the light beam entering a substrate by intensity changing or phase changing one part of the light beam corresponding to a pattern shape to form on the substrate; and
interfering the light beam exit from the light path changing section and the adjusting section on the substrate to carry out interference exposure on the substrate.

12. The interference exposure method according to claim 11, wherein
the light path changing section is configured to include a diffraction grating arranged in a ring-shape in a plane substantially perpendicular to the light beam, and
the light path direction and the light path length of the plurality of light beams are changed with the diffraction grating.

13. The interference exposure method according to claim 11, wherein
the light path changing section is configured to include a plurality of micro-mirrors,
the micro-mirrors are arranged in a ring-shape to configure a tubular inner wall surface by each mirror surface, and
the light path direction and the light path length of the plurality of light beams are changed by the micro-mirror.

14. The interference exposure method according to claim 11, wherein
the light path changing section is configured to include a first prism of a circular cone shape and a second prism of a polyangular cone shape, and
the light path direction and the light path length of the plurality of light beams are changed by the first or second prism.

15. The interference exposure method according to claim 11, further comprising the step of filtering the light beam with a filtering section configured to filter an angle at which the light beam enters the substrate.

16. A manufacturing method of a semiconductor device comprising the steps of:
changing a light path direction and a light path length of a plurality of light beams with a light path changing section in which a changing element adapted to change a light path direction and a light path length of the plurality of light beams having coherency with respect to each other is arranged substantially axisymmetrically;
adjusting one part of the light beam with an adjusting section configured to adjust one part of the light beam entering a substrate by intensity changing or phase changing one part of the light beam corresponding to a pattern shape to form on the substrate;
interfering the light beam exit from the light path changing section and the adjusting section on the substrate to carry out interference exposure on the substrate; and
processing the substrate from above a resist pattern formed on the substrate by the interference exposure to form a substrate pattern corresponding to the resist pattern.

17. The manufacturing method of the semiconductor device according to claim 16, wherein
the light path changing section is configured to include a diffraction grating arranged in a ring-shape in a plane substantially perpendicular to the light beam, and
the light path direction and the light path length of the plurality of light beams are changed with the diffraction grating.

18. The manufacturing method of the semiconductor device according to claim 16, wherein
the light path changing section is configured to include a plurality of micro-mirrors,
the micro-mirrors are arranged in a ring-shape to configure a tubular inner wall surface by each mirror surface, and
the light path direction and the light path length of the plurality of light beams are changed by the micro-mirror.

19. The manufacturing method of the semiconductor device according to claim 16, wherein
the light path changing section is configured to include a first prism of a circular cone shape and a second prism of a polyangular cone shape, and
the light path direction and the light path length of the plurality of light beams are changed by the first or second prism.
